(19) United States
(12) Patent Application Publication
(10) Pub. No.: US 2020/0375027 A1
(43) Pub. Date: Nov. 26, 2020

(54) Single Layer PCB Circuit Layout For Uniform Radial LED Array

(71) Applicant: Applied Materials, Inc., Santa Clara, CA (US)

(72) Inventors: Jason M. Schaller, Austin, TX (US); Robert Brent Vopat, Austin, TX (US); Paul E. Pergande, Austin, TX (US)

(21) Appl. No.: 16/417,886

(22) Filed: May 21, 2019

(51) Int. Cl. H05K 1/02

(52) U.S. Cl. CPC H05K 1/0296; H05K 1/0284; H05K 2201/10522; H05K 2201/09018; H05K 2201/10106

(57) ABSTRACT

A system for heating substrates comprising LEDs arranged in a plurality of concentric circles is disclosed. The system comprises an array of light emitting diodes (LEDs) disposed in a two-dimensional grid, where there are a set of rows, and each row comprises a plurality of LEDs configured in parallel. This configuration is fault tolerant, allowing one or more LEDs to be inoperable, without affecting any of the other LEDs. Further, the LEDs are arranged in concentric circles, allowing uniform heating of the substrate. Additionally, in certain embodiments, the LEDs and signal traces are arranged so that a single layer circuit board may be used. A method of creating this array of LEDs is also disclosed.

### FIELD

Embodiments of the present disclosure relate to system for heating a substrate, and more particularly, a system comprising a printed circuit board having LEDs arranged in concentric circles.

### BACKGROUND

The fabrication of a semiconductor device involves a plurality of discrete and complex processes. The semiconductor substrate typically undergoes many processes during the fabrication process. These processes may occur in a processing chamber, which may be maintained at a different processing condition than the environment.

Heating substrates before and/or after processing is common in many semiconductor fabrication processes. In many cases, the substrate is heated to a temperature close to the process temperature and then transported to the platen. This preheating may help prevent substrate warping, popping and movement when the cold substrate contacts the hot platen. These phenomena may cause the creation of particles and mishandling, and may reduce overall process yield.

Additionally, in some embodiments, a substrate may be warmed after being subjected to a cold process to eliminate the possibility of condensation when the substrate exits the processing chamber.

In certain embodiments, a dedicated preheating station may be used to perform this function. The preheating station may comprise one or more infrared lamps that are focused on the substrate. While the preheating station is effective at raising the temperature of the substrate, the preheating station has a negative impact on throughput. Specifically, a substrate may be disposed at the preheating station for a significant amount of time in order for the substrate to reach the desired temperature. Further, infrared lamps utilize considerable power.

It would be beneficial if there were an apparatus to heat the substrates using light emitting diodes (LEDs). Further, it would be advantageous if the LEDs were arranged in concentric circles and also were electrically connected in a fault tolerant manner.

### SUMMARY

A system for heating substrates comprising LEDs arranged in a plurality of concentric circles is disclosed. The system comprises an array of light emitting diodes (LEDs) disposed in a two-dimensional grid, where there are a set of rows, and each row comprises a plurality of LEDs configured in parallel. This configuration is fault tolerant, allowing one or more LEDs to be inoperable, without affecting any of the other LEDs. Further, the LEDs are arranged in concentric circles, allowing uniform heating of the substrate. Additionally, in certain embodiments, the LEDs and signal traces are arranged so that a single layer circuit board may be used. A method of creating this array of LEDs is also disclosed.

According to one embodiment, a heating system is disclosed. The heating system comprises a printed circuit board; and light emitting diodes (LEDs) arranged in concentric circles on the printed circuit board, wherein the LEDs are electrically configured as one or more grids, each grid having a first plurality of rows, wherein each row comprises a second plurality of LEDs in parallel. In certain embodiments, the printed circuit board comprises exactly one signal routing layer. In certain embodiments, the LEDs are configured as a plurality of grids, wherein each grid forms a zone, where a zone comprises a center circle of an annular ring. In a further embodiment, the system comprises a plurality of grid power supplies, each in communication with a respective zone, such that LEDs in each zone is independently controlled. In certain embodiments, the number of rows in each grid is determined based on a grid voltage and a voltage drop across each LED. In certain embodiments, the grid voltage is about 300V and he number of rows in each grid is 80 or more and the number of columns in each grid is 5 or more.

According to another embodiment, a method of creating a heating system having a plurality of LEDs arranged in concentric circles, wherein the plurality of LEDs are electrically configured in grids, each grid having a first plurality of rows, wherein each row comprises a second plurality of LEDs in parallel, the second plurality defined as C, is disclosed. The method comprises determining a nominal circumferential pitch and a nominal radial pitch; creating an initial array, wherein the concentric circles are separated by the nominal radial pitch; determining a number of LEDs for each concentric circle, wherein a maximum number of LEDs in each concentric circle is determined based on a radius of the concentric circle and the nominal circumferential pitch, and wherein the number of LEDs in each concentric ring is less than the maximum number and is an odd multiple of C; and arranging the plurality of LEDs on a printed circuit board in concentric circles, each concentric circle having the number of LEDs previously determined. In certain embodiments, the method further comprises defining a plurality of zones, each zone being a center circle or an annular ring, wherein a zone comprises an integral number of grids. In certain embodiments, the method further comprises adjusting a number of LEDs in one or more concentric circles within a zone, so that the total number of LEDs in each zone is within 10% of each other. In certain further embodiments, the number of LEDs is adjusted by adding or removing rows from the grid, and wherein the number of columns remains unchanged. In certain embodiments, the method further comprises adjusting a radial pitch between one or more concentric rings to improve heating uniformity. In certain embodiments, a block comprises a set of C LEDs that are in parallel, and a number of blocks in a concentric circle is equal to the odd multiple of C determined previously, where the LEDs in adjacent blocks within a concentric circle are arranged in opposite orientation, such that anodes in one block face toward an outer edge of the printed circuit board and anodes in the adjacent block face a center of the printed circuit board.

According to another embodiment, a heating system is disclosed. The heating system comprises an arcuate printed circuit board; and light emitting diodes (LEDs) arranged in fractional concentric circles on the arcuate printed circuit board, wherein the LEDs are electrically configured as one or more grids, each grid having a first plurality of rows, wherein each row comprises a second plurality of LEDs in parallel. In certain embodiments, the arcuate printed circuit board comprises a quarter annular ring.

In another embodiment, a method of fabricating the heating system described above is disclosed. In this embodiment, the second plurality is defined as C and the method comprises determining a nominal circumferential pitch and a nominal radial pitch; creating an initial array, wherein the fractional concentric circles are separated by the nominal radial pitch; determining a number of LEDs for each fractional concentric circle, wherein a maximum number of LEDs in each fractional concentric circle is determined based on a radius of the fractional concentric circle, the fraction, and the nominal circumferential pitch, and wherein the number of LEDs in each fractional concentric ring is less than the maximum number and is an odd multiple of C; and arranging the LEDs on the arcuate printed circuit board in fractional concentric circles, each fractional concentric circle having the number of LEDs previously determined. In certain embodiments, the method further comprises defining a plurality of zones, each zone being a fractional annular ring, wherein a zone comprises an integral number of grids; and adjusting a number of LEDs in one or more fractional concentric circles within a zone, so that the total number of LEDs in each zone is within 10% of each other. In certain embodiments, the number of LEDs is adjusted by adding or removing rows from the grid, and wherein the number of columns remains unchanged. In certain embodiments, the method further comprises adjusting a radial pitch between one or more concentric rings to improve heating uniformity. In certain embodiments, a block comprises a set of C LEDs that are in parallel, and a number of blocks in a concentric circle is equal to the odd multiple of C determined previously, where the LEDs in adjacent blocks within a concentric circle are arranged in opposite orientation, such that anodes in one block face toward an outer edge of the arcuate printed circuit board and anodes in the adjacent block face a center of the arcuate printed circuit board.

### BRIEF DESCRIPTION OF THE FIGURES

For a better understanding of the present disclosure, reference is made to the accompanying drawings, which are incorporated herein by reference and in which:

FIG. 1 is a top view of a LED grid, arranged in rows and columns;

FIG. 2 is a sequence showing a method to create the desired array;

FIG. 3 shows how current travels from one concentric ring to another;

FIG. 4 shows how multiple concentric circles can be treated as a single entity;

FIG. 5 shows the LED array created using the sequence shown in FIG. 2;

FIG. 6 shows the flow of current through the zones on the LED array of FIG. 5;

FIG. 7 shows the placement of the LEDs in the LED array; and

FIG. 8 shows arcuate printed circuit boards that may also be used in certain embodiments.

### DETAILED DESCRIPTION

As described above, in many applications, it is advantageous to heat a substrate. Further, the use of LEDs has many advantages over the use of infrared heat lamps. For example, the LED array may be much more compact, consuming much less space. Further, the LED array may consume less power.

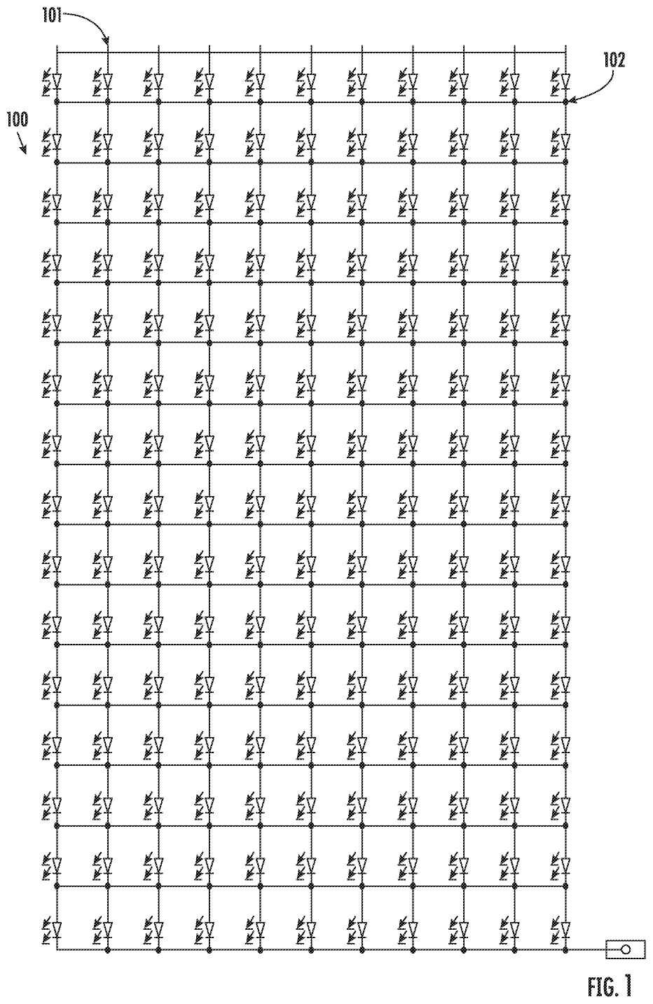

FIG. 1 shows a grid 100 of LEDs, arranged in columns 101 and rows 102. The rows 102 are arranged in series electrically, where the anodes of the LEDs in the top row are electrically connected to the grid power supply and the cathodes of the LEDS in the bottom row is electrically connected to ground. The number of rows may be a function of the grid voltage provided to the grid 100 by the grid power supply. For example, the number of rows should be limited to less than the grid voltage divided by the voltage drop across a single LED. Each LED may experience a voltage drop of about 3V. Therefore, the total number of rows is preferably less than the grid voltage divided by 3. However, the grid power supply may have a tolerance, such as 10%. Therefore, for a grid voltage of 300V, the minimum voltage may be 270V and the maximum number of rows would be 90. Of course, the number of rows may be less than the maximum value calculated, but preferably is not greater than this value. Of course, if the voltage drop across each LED is different than this value or the grid voltage is different, the number of rows may differ.

In each row 102 of the grid 100, there are a second plurality of LEDs that are arranged in parallel. In the grid 100 shown in FIG. 1, there are 15 rows and 11 columns. The use of multiple columns improves the fault tolerance of the grid 100.

For example, if one LED was to become inoperable, the current that would normally pass through that LED is rerouted through all of the other LEDs that are in the same row. The determination of the appropriate number of columns is driven by two factors. The first factor is the current capability of the grid power supply. The maximum number of columns is defined so that the grid power supply can supply the current to all of these columns. The second factor is the maximum current that each LED can pass. For example, if there are only two columns, if one LEDs ceases to function, the current through the second LED that is in parallel with the inoperable LED doubles. With ten columns, if one LED ceases to function, the current through the remaining nine LEDs that are in parallel with the inoperable LED increases by only 11%.

While FIG. 1 shows a grid having 15 rows and 11 columns, other dimensions are also possible. For example, in the case where the grid voltage is 300V, the grid may have approximately rows. In certain embodiments, if the grid voltage is 300V, the number of rows may be 80 or more, and the number of columns may be between 5 and 11. If the grid voltage is lower, such as 100V, the number of rows may be reduced to 30 or less.

While the grid 100 shown in FIG. 1 is very effective at producing a great amount of heat in a fault tolerant manner, it has drawbacks. Specifically, most substrates are round, not rectangular. Thus, to heat a substrate that has a diameter D, the grid may be at least D×D in size. Thus, over 20% of the grid is not located above the substrate! This results in a grid that is overly large and wasteful of energy. A better solution would be to arrange the grid as a number of concentric circles. In addition, process uniformity often has a radial dependence. Thus, the ability to tune the temperature radially by controlling the LEDs disposed in various annular rings helps offset radial non-uniformities caused by other factors. An array arranged as concentric circles addresses this issue.

However, such a configuration is not trivial. As described above, the grid 100 has a first plurality of rows and a second plurality of columns. This electrical configuration is still desirable, even though the physical configuration has changed.

Another complication is that these LEDs consume a large amount of power. Each LED may be a high power LED, which emits light of a wavelength or a plurality of wavelengths that is readily absorbed by the substrates. For example, silicon exhibits high absorptivity and low transmissivity in the range of wavelengths between about 0.4 and 1.0 μm. Silicon absorbs more than 50% of the energy emitted in the range of wavelengths from 0.4 to 1.0 μm. LEDs that emit light in this range of wavelengths may be used. In certain embodiments, LEDs made from GaN are employed. These GaN LEDs emit light at a wavelength of about 450 nm. In certain embodiments, GaP LEDs are employed, which emit light at a wavelength between 610 and 760 nm.

The LEDs which make up the grid 100 may be varied in size. In certain embodiments, each LED may be 1.3 mm×1.7 mm. In another embodiment, each LED may be 1 mm×1 mm. Of course, LEDs of other dimensions are also within the scope of the disclosure.

Each LED may consume up to 3 W. Therefore, a grid having 84 rows and 11 columns will consume over 924×3 W, or 2.77 kW. An array having 5 or 6 grids would consume over 13 kW. In order to dissipate this amount of power, it is preferably that the circuit board on which the grid 100 is mounted contain a single layer of conductive material used for routing signals. In this way, the circuit board may have a metal base and be able to efficiently conduct the heat away from the LEDs and toward a heat sink, which may be mounted to the back surface of the circuit board. Traditionally, circuit boards with multiple conductive layers that are used for routing signals are constructed with dielectric materials separating the conductive layers. These dielectric layers significantly impact the ability to conduct the heat from the LEDs on the top surface to the heat sink, located adjacent to the bottom surface.

However, the use of a printed circuit board with only one layer used for routing signals implies that no signal trace can cross any other signal trace. Thus, the creation of a heating system employing an array of LEDs has several desired characteristics:
Maintains the electrical configuration of rows and columns;
Readily removes heat from the LEDs;
Is arranged with concentric circles to allow the tuning of power applied to each zone; and
Uniformly heats the substrate.

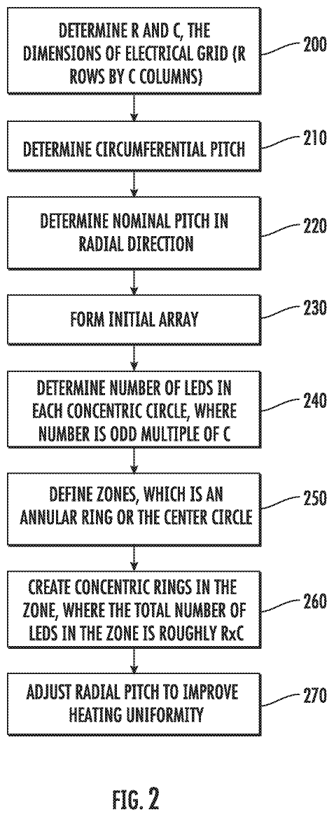

FIG. 2 shows a sequence of processes that may be used to create an LED array that has these characteristics.

First, as shown in Process 200, the size of the grid is determined. As described above, the grid has a first plurality of rows, referred to as R and a second plurality of columns, referred to as C. The number of rows may be a function of the grid voltage, while the number of columns may be a function of the current capability of the grid power supply and the amount of fault tolerance desired.

Next, as shown in Process 210, the circumferential pitch is determined. This may be done by first establishing the minimum and maximum die spacing in the circumferential direction. This may be referred to as the circumferential pitch and represents the distance between two adjacent LEDs in the same concentric circle. The minimum die spacing is a function of the physical constraints. Specifically, each LED has a certain die size. The spacing between LEDs cannot be less than this die size. The maximum die spacing may be set based on expected heating uniformity. In other words, if adjacent LEDs are spaced too far apart, the resulting heat profile may be non-uniform. Based on the minimum and maximum circumferential pitch, a nominal circumferential pitch can then be determined. In another embodiment, the nominal circumferential pitch may be determined first, and the minimum and maximum pitch may then be determined based on the nominal circumferential pitch.

Next, as shown in Process 220, the nominal pitch in the radial direction is determined. This may be referred to as the radial pitch and represents the distance between two adjacent concentric circles. In certain embodiments, a maximum pitch in the radial direction may also be determined. This maximum radial pitch may be set based on expected heating uniformity. In other words, if adjacent concentric circles are spaced too far apart or too close together, the resulting heat profile may be non-uniform.

Having defined all of the parameters, the process of actually configuring the array may begin. First, an initial array may be tentatively created as shown in Process 230, where the spacing between adjacent concentric circles is defined as the nominal radial pitch, determined in Process 220. For example, an array where concentric circles have radii that are increments of 2.5 mm may be tentatively created.

Next, as shown in Process 240, the number of LEDs in each concentric circle is determined. This can be done by first calculating the circumference of each concentric circle, and dividing that circumference by the minimum circumferential pitch. This calculation results in the maximum number of LEDs that may exist in that concentric circle. However, in order to maintain the grid configuration, the number of LEDs in each concentric circle is reduced so that it is divisible by C, the number of columns in the grid. Furthermore, in order to route the signal traces on one layer, the number of LEDs in each concentric circle is an odd multiple of C. This odd multiple is the number of blocks of LEDs in that concentric ring, where a block is a set of C LEDs in parallel.

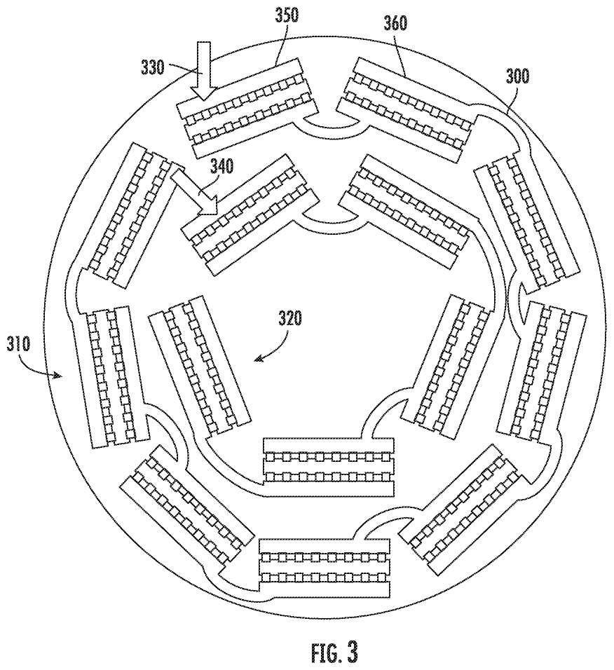

The reason for this limitation is shown in FIG. 3. The current paths 300 are shown. Current passes through a group, which comprises one of more blocks of C LEDs in parallel, and then is routed to the next group of LEDs. Note that in order for current to pass from an outer concentric circle 310 to an inner concentric circle 320, the current enters on the outer edge of that outer concentric circle as shown by arrow 330 and exits on the inner edge of that concentric circle, as shown by arrow 340. This can only be achieved if the number of groups is odd. Further, adjacent groups are arranged in opposite directions. For example, the anodes of the LEDs in Group 350 may face toward the outer edge, but the anodes of the LEDs in adjacent Group 360 face toward the center. Thus, the current path snakes between adjacent groups in a zig-zig pattern.

Thus, using the circumference, the minimum circumferential pitch and the stipulation that the number of LEDs in each concentric circle is an odd multiple of C, the maximum number of LEDs in each concentric circle can be determined.

As example of this calculation is given below. Assume that the minimum circumferential pitch is 2.35 mm and the grid has dimensions of 84 rows and 11 columns. In other words, C is equal to 11. If the radius of the concentric circle is 15 mm, the circumference is 94 mm and the maximum number of LEDs is 94/2.35 or 40. Thus, 33 LEDs may be used in this concentric circle. The actual circumferential pitch would be 94/33 or 2.84 mm. As another example, assume a radius of 100 mm. The circumference would be 628 mm and the maximum number of LEDs would be 267. The largest odd multiple of C that is less than 267 is 253. The actual circumferential pitch would be 628/253 or 2.48.

It is noted that the actual number of LEDs in a concentric circle may be less than the maximum odd multiple of C. For example, in the previous example, 187 209, or 231 LEDs may also be used for this concentric circle if desired. By using a smaller number of LEDs in a particular concentric circle, it may be possible to group adjacent concentric circles into groups, as described in more detail below.

Next, as shown in Process 250, the array is separated into a plurality of zones. A zone is defined as an annular ring containing a plurality of concentric circles, or as the center circle. Each zone comprises an integral number of grids. In certain embodiments, each zone is exactly one grid. A zone may also in communication with a dedicated grid power supply, which supplied the power to this particular zone. In this way, the heating of each zone can be independently controlled.

Once the number of LEDs in each concentric circle is determined, the number of concentric circles in a zone can be calculated, as shown in Process 260. The number of concentric circles in a zone is such that the total number of blocks of C LEDs is approximately equal to R. Stated differently, the total number of LEDs in a zone is approximately equal to R×C. In certain embodiments, the number of LEDs in one or more concentric circles in a zone may be reduced or increased to ensure that the total number of LEDs in the zone satisfies the above limitation. In certain embodiments, the number of LEDs in a zone may be within 10% of R×C. In other words, the number of rows may be adjusted by 10% to allow the zone to be an annular ring or a center circle, while the number of columns remains unchanged. This constraint allows ease of routing and supplying power and ground. Further, this constraint allows each zone to be an annular ring, and the power to that annular ring may be independently controlled.

Finally, the radial pitch between adjacent concentric circles may be adjusted to improve heating uniformity, as shown in Process 270. For example, in one embodiment, the radii of the concentric circles may be adjusted so that the LED density, which is the number of LEDs per unit area, is relatively constant.

Once the zones have been created, and the number of LEDs in each concentric circle is determined, the signal traces may be created and the LEDs can be arranged on the printed circuit board. Blocks of LEDs that are in rows that are in the same concentric circle and are adjacent to each other are placed in mirror configuration. In other words, the first block of LEDs may be oriented with its anodes facing toward outer edge of the printed circuit board. The second block is then oriented with its anodes facing the center of the printed circuit board.

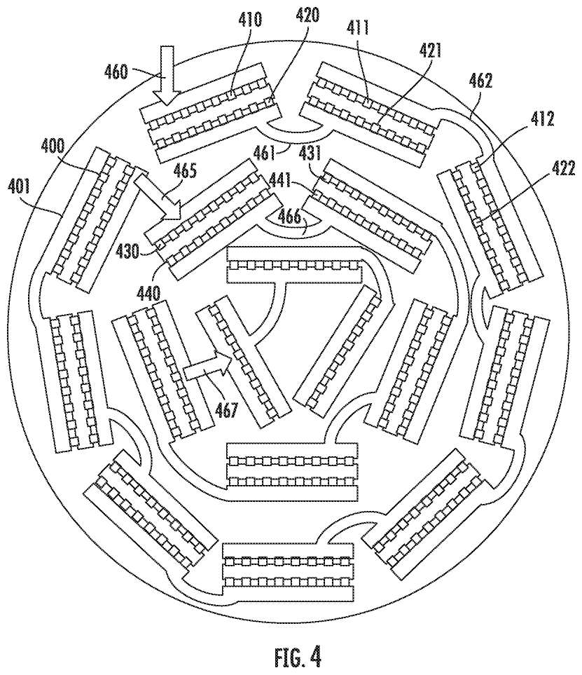

In one enhancement to this sequence, concentric circles with the same number of LEDs may be treated as a single entity. For example, an example configuration showing a number of concentric circles and the LEDs in each one is shown in Table 1 below. A partial schematic of this configuration is shown in FIG. 4. In this figure, C, the number of LEDs in parallel, is set to 8. In each concentric circle, each set of eight LEDs 400 are sandwiched between two busbars 401.

TABLE 1

| Row | Number |
|---|---|
| Number | of LEDS |
| 1 | 24 |
| 2 | 40 |
| 3 | 40 |
| 4 | 72 |
| 5 | 72 |

In this case, rather than routing the signal traces to accommodate only Row #5 (i.e. the outermost row in FIG. 4), the signal traces can be created to accommodate Rows #4 and Row #5 at once. In other words, two blocks of 8 LEDs are adjacent in the radial direction and are electrically connected. These two blocks of LEDs form a group. The current travels through trace 460 to the busbar and to the anodes of the first block 410 of Row #5 and then to the anodes of the first block 420 in Row #4. The trace 461 then travels circumferentially to the anodes in the second block 421 of Row #4 and to the anodes of the second block 411 of Row #5. The trace 462 travels circumferentially from the cathodes of the second block 411 of Row #5 to the anodes of the third block 412 of Row #5 and passes to the anodes of the third block 422 of Row #4. This repeats for each block in Row #4 and Row #5. When traces are routed to all of the groups in Row #4 and Row #5, the trace 465 exits from the inner edge of

Row #4. This allows routing to Row #3.

Row #2 and Row #3 each have 40 LEDs and therefore can be grouped as a single entity in a manner similar to Row #4 and Row #5. Thus, current enters the anodes of the LEDs in the first block 430 of Row #3, and passes to the anodes of the first block 440 of Row #2. The current travel circumferentially through trace 466 to the second block 441 in Row #2 and then passes to the second block 431 in Row #3. This repeated around the rest of these two concentric circles until current has been delivered to all of the LEDs in these two rows. Again, because the number of LEDs in Row #3 and Row #2 is an odd multiple of C, the current enters Row #3 through trace 465 on the outer edge of Row #3 and exits through trace 467 on the inner edge of Row #2. This allows current to be provided to the innermost row, Row #1.

Since Row #1 is the only circle having 24 LEDs, it is created by itself.

While this figure shows the current traveling from an outer edge toward the center, it is understood that the grid power supply may be oriented such that the current travels in the opposite direction, from the innermost row and flowing outward.

In addition to simplifying the routing of the traces on the printed circuit board, the ability to group blocks in different rows allows for the use of busbars, which may be thicker than other traces. These busbars spread the heat better and improve thermal conductivity.

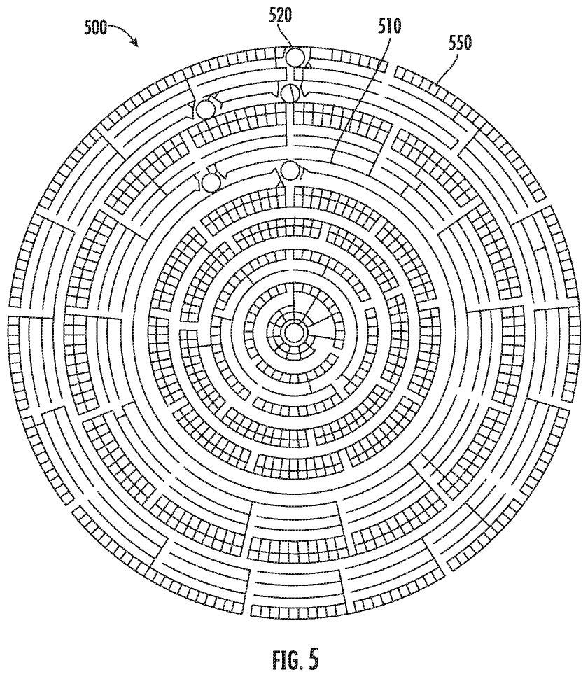

FIG. 5 shows the signal traces for one such array 500. This signal traces are disposed on the top layer of a printed circuit board. In certain embodiments, the printed circuit board may comprise a metal substrate, such as aluminum or copper. This metal substrate may be of any desired thickness, such as 0.06 inches or more. A dielectric layer having minimal thermal resistance is provided on top of the metal substrate. This dielectric layer may be 0.01 inches or less in certain embodiments. A single conductive routing layer is selectively disposed on the dielectric layer. The single conductive routing layer may a standard printed circuit foil having a thickness of ounce to 10 ounces. The objective of the sequence shown in FIG. 2 is to create a configuration that allows all of the electrical connections to be made using the single conductive routing layer. This is demonstrated by the signal traces in FIG. 5.

The concentric circles 510 are visible in this figure. Additionally, it can be seen that some concentric circles have be linked to form groups, such as group 550 along the outer edge. The large holes 520 represent the pass through connections for the grid voltage and ground. Note that, with the exception of the pass through connections for power and ground, there are no other pass through vias in this printed circuit board.

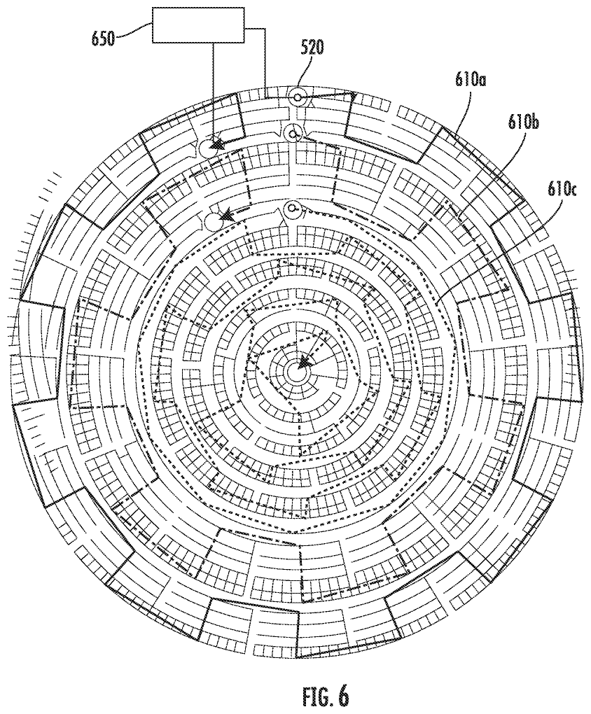

FIG. 6 shows the flow of current through the three zones in the array 500. In each zone, the current 610a, 610b, 610c enters at one of the large holes 520 and exits at a second large hole 520. As explained above, the current passes in a somewhat zig-zag pattern as it moves through the various groups of LEDs. A grid power supply 650 is shown in communication with two of these large holes 520 so as to provide power and ground for that zone. Similar grid power supplies (not shown) are in communication with the remaining four large holes 520. Note that while FIG. 6 shows the current travelling from a location on the printed circuit board to a location closer to the center, the grid power supply may be configured so that the current flows in the opposite direction.

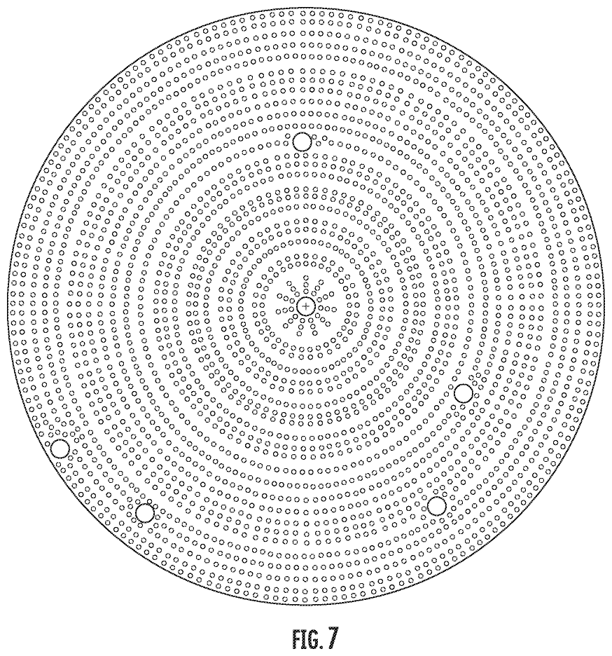

FIG. 7 shows the placement of the LEDs in the array 500. As can be seen, the LEDs are arranged in concentric circles where the circumferential pitch decreases as the radius grows smaller. The placement of the LEDs allows for uniform heating.

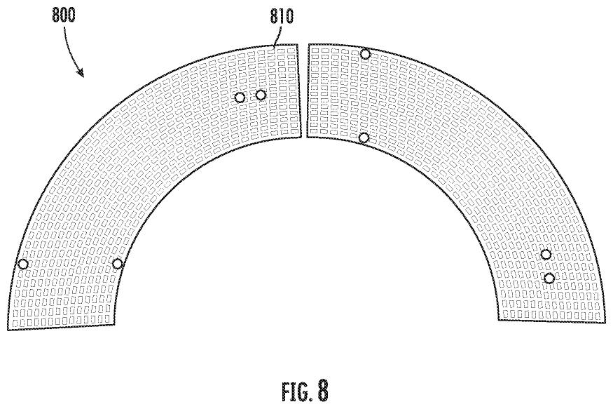

While the above disclosure describes the creation of a circular LED array, there may be other embodiments. For example, the printed circuit board may be formed as a quarter annular ring, as shown in FIG. 8. In another embodiment, the printed circuit board may be formed as a half annular ring. In fact, the annular ring may be divided into any number of smaller printed circuit boards. These fractional annular rings are referred to as arcuate printed circuit boards.

The LEDs 810 are arranged in fractional concentric circles, as can be seen in FIG. 8. The inner and outer radius of the arcuate printed circuit board 800 may vary and are not limited by this disclosure.

The use of arcuate printed circuit boards 800, which in certain embodiments, may be configured as quarter annular rings, is desirable to independently control the heating per quadrant. For example, in a large chamber, there may be inherently uneven heating. Thus, by using quarter annular rings, each quadrant of the chamber can be independently heated.

The sequence of FIG. 2 is still used for this configuration. The only difference that the calculation shown in Process 230 is slightly modified. Rather than determining the number of LEDs for the entire concentric circle, the number of LEDs for this portion of the annular ring is determined. In other words, if the printed circuit board shown in FIG. 8 is used, the circumference of the concentric circle is divided by 4, as this is a quarter of the entire concentric circle. This value is then divided by the nominal circumferential pitch to give the maximum number of LEDs in this concentric quarter-circle. This number is then used to determine the number of LEDs in that concentric quarter-circle with the proviso that the number is an odd multiple of C. The remaining processes are the same as was described above.

The embodiments described above in the present application may have many advantages. First, in certain embodiments, LEDs may be preferable to an infrared heat lamp. These LED arrays are more compact and use less power. Further, the configuration described herein is fault tolerant, allowing one or more LEDs to cease operating and not affect any other LEDs. Additionally, the LED is constructed so that the signal traces can all be on a single routing layer. This allows the use of a printed circuit board having a single layer for routing signals, which is much more efficient in removing the heat from the LEDs. Further, the

LEDs are disposed in zones on the circuit board to allow uniform heating. Through the creation of zones, the power to each zone can be independently controller, allowing more uniform heating.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A heating system, comprising:
a printed circuit board; and
light emitting diodes (LEDs) arranged in concentric circles on the printed circuit board, wherein the LEDs are electrically configured as one or more grids, each grid having a first plurality of rows, wherein each row comprises a second plurality of LEDs in parallel.

2. The heating system of claim 1, wherein the printed circuit board comprises exactly one signal routing layer.

3. The heating system of claim 1, wherein the LEDs are configured as a plurality of grids, wherein each grid forms a zone, wherein a zone comprises a center circle or an annular ring.

4. The heating system of claim 3, further comprising a plurality of grid power supplies, each in communication with a respective zone, such that LEDs in each zone are independently controlled.

5. The heating system of claim 1, wherein a number of rows in each grid is determined based on a grid voltage and a voltage drop across each LED.

6. The heating system of claim 5, wherein the grid voltage is about 300V and the number of rows in each grid is 80 or more.

7. The heating system of claim 6, wherein a number of columns in each grid is 5 or more.

8. A method of creating a heating system having a plurality of LEDs arranged in concentric circles, wherein the plurality of LEDs are electrically configured in grids, each grid having a first plurality of rows, wherein each row comprises a second plurality of LEDs in parallel, the second plurality defined as C, the method comprising:
determining a nominal circumferential pitch and a nominal radial pitch;
creating an initial array, wherein the concentric circles are separated by the nominal radial pitch;
determining a number of LEDs for each concentric circle, wherein a maximum number of LEDs in each concentric circle is determined based on a radius of the concentric circle and the nominal circumferential pitch, and wherein the number of LEDs in each concentric circle is less than the maximum number and is an odd multiple of C; and
arranging the plurality of LEDs on a printed circuit board in concentric circles, each concentric circle having the number of LEDs previously determined.

9. The method of claim 8, further comprising:
defining a plurality of zones, each zone being a center circle or an annular ring, wherein a zone comprises an integral number of grids.

10. The method of claim 9, further comprising:
adjusting the number of LEDs in one or more concentric circles within a zone, so that a total number of LEDs in each zone is within 10% of each other.

11. The method of claim 10, wherein the number of LEDs is adjusted by adding or removing rows from the grid, and wherein a number of columns remains unchanged.

12. The method of claim 8, further comprising:
adjusting a radial pitch between one or more concentric circles to improve heating uniformity.

13. The method of claim 8, wherein a block comprises a set of C LEDs that are in parallel, and a number of blocks in a concentric circle is equal to the odd multiple of C determined previously, where the LEDs in adjacent blocks within a concentric circle are arranged in opposite orientation, such that anodes in one block face toward an outer edge of the printed circuit board and anodes in the adjacent block face a center of the printed circuit board.

14. A heating system, comprising:
an arcuate printed circuit board; and
light emitting diodes (LEDs) arranged in fractional concentric circles on the arcuate printed circuit board, wherein the LEDs are electrically configured as one or more grids, each grid having a first plurality of rows, wherein each row comprises a second plurality of LEDs in parallel.

15. The heating system of claim 14, wherein the arcuate printed circuit board comprises a quarter annular ring.

16. A method of fabricating the heating system of claim 14, wherein the second plurality is defined as C, the method comprising:
determining a nominal circumferential pitch and a nominal radial pitch;
creating an initial array, wherein the fractional concentric circles are separated by the nominal radial pitch;
determining a number of LEDs for each fractional concentric circle, wherein a maximum number of LEDs in each fractional concentric circle is determined based on a radius of the fractional concentric circle, the fraction, and the nominal circumferential pitch, and wherein the number of LEDs in each fractional concentric circle is less than the maximum number and is an odd multiple of C; and
arranging the LEDs on the arcuate printed circuit board in fractional concentric circles, each fractional concentric circle having the number of LEDs previously determined.

17. The method of claim 16, further comprising:
defining a plurality of zones, each zone being a fractional annular ring, wherein a zone comprises an integral number of grids; and
adjusting a number of LEDs in one or more fractional concentric circles within a zone, so that a total number of LEDs in each zone is within 10% of each other.

18. The method of claim 17, wherein the number of LEDs is adjusted by adding or removing rows from the grid, and wherein a number of columns remains unchanged.

19. The method of claim 16, further comprising:
adjusting a radial pitch between one or more fractional concentric circles to improve heating uniformity.

20. The method of claim 16, wherein a block comprises a set of C LEDs that are in parallel, and a number of blocks in a fractional concentric circle is equal to the odd multiple of C determined previously, wherein the LEDs in adjacent blocks within a fractional concentric circle are arranged in opposite orientation, such that anodes in one block face toward an outer edge of the arcuate printed circuit board and anodes in the adjacent block face a center of the arcuate printed circuit board.
